(19) United States
(12) Patent Application Publication
(10) Pub. No.: US 2020/0251884 A1
(43) Pub. Date: Aug. 6, 2020

(54) SEMICONDUCTOR LASER ELEMENT AND METHOD OF MANUFACTURING THE SAME

(71) Applicant: SHARP KABUSHIKI KAISHA, Sakai City (JP)

(72) Inventors: RYOTA KAWAMURA, Sakai City (JP); TOSHIYUKI KAWAKAMI, Sakai City (JP)

(21) Appl. No.: 16/782,391

(22) Filed: Feb. 5, 2020

Related U.S. Application Data
(60) Provisional application No. 62/802,133, filed on Feb. 6, 2019.

(51) Int. Cl. H01S 5/042; H01S 5/32; H01S 5/20; H01S 5/028

(52) U.S. Cl. CPC H01S 5/04254; H01S 5/3211; H01S 5/2086; H01S 5/0281; H01S 5/2059

(57) ABSTRACT

A semiconductor laser element includes: a substrate; a first-conductivity-type semiconductor layer formed on the substrate; a light-emitting layer formed on the first-conductivity-type semiconductor layer; a second-conductivity-type semiconductor layer that is formed on the light-emitting layer and includes a protrusion in a strip form; a transparent conductive layer formed on the protrusion of the second-conductivity-type semiconductor layer; a protective layer that is formed on the transparent conductive layer and has conductivity; a dielectric film that covers side surfaces of the protrusion of the second-conductivity-type semiconductor layer, side surfaces of the transparent conductive layer, and side surfaces of the protective layer; and an upper electrode formed on the protective layer. The whole of an upper surface of the transparent conductive layer is covered by the protective layer, and part of an upper surface of the protective layer is covered by the dielectric film.

### TECHNICAL FIELD

The present invention relates to a semiconductor laser element and a method of manufacturing the same.

### BACKGROUND ART

For example, PTL 1 discloses a semiconductor laser element that includes a conductive oxide layer formed on an upper surface of a ridge, a dielectric layer formed on side surfaces of the ridge, and a pad electrode covering the conductive oxide layer and the dielectric layer.

### CITATION LIST

### Patent Literature

[PTL 1] Japanese Unexamined Patent Application Publication No. 2011-222973

### SUMMARY OF INVENTION

### Technical Problem

However, in the semiconductor laser element of the cited literature 1, the pad electrode that directly covers the conductive oxide layer absorbs laser-emitted light, thus causing loss of the emitted light.

An aspect of the invention achieves a semiconductor laser element in which loss of laser-emitted light is small and a method of manufacturing the same.

### Solution to Problem

A semiconductor laser element according to an aspect of the invention includes: a substrate; a first-conductivity-type semiconductor layer that is formed on the substrate; a light-emitting layer that is formed on the first-conductivity-type semiconductor layer; a second-conductivity-type semiconductor layer that is formed on the light-emitting layer and includes a protrusion in a strip form; a transparent conductive layer that is formed on the protrusion of the second-conductivity-type semiconductor layer; a protective layer that is formed on the transparent conductive layer and has conductivity; a dielectric film that covers side surfaces of the protrusion of the second-conductivity-type semiconductor layer, side surfaces of the transparent conductive layer, and side surfaces of the protective layer; and an upper electrode that is formed on the protective layer, in which a whole of an upper surface of the transparent conductive layer is covered by the protective layer, and part of an upper surface of the protective layer is covered by the dielectric film.

In the semiconductor laser element according to an aspect of the invention, an end of the upper surface of the protective layer is covered by the dielectric film.

A refractive index of the transparent conductive layer with respect to light emitted from the light-emitting layer is lower than a refractive index of the second-conductivity-type semiconductor layer with respect to the light emitted from the light-emitting layer.

The transparent conductive layer includes a first transparent conductive layer and a second transparent conductive layer that is formed on the first transparent conductive layer, and a refractive index of the second transparent conductive layer with respect to light emitted from the light-emitting layer is lower than a refractive index of the first transparent conductive layer with respect to the light emitted from the light-emitting layer.

In the semiconductor laser element according to an aspect of the invention, the transparent conductive layer includes a first transparent conductive layer and a second transparent conductive layer that is formed on the first transparent conductive layer, and the second transparent conductive layer has an electrical resistance lower than an electrical resistance of the first transparent conductive layer.

In the semiconductor laser element according to an aspect of the invention, the first transparent conductive layer and the second transparent conductive layer are made from ITO, and the first transparent conductive layer contains more oxygen than the second transparent conductive layer.

In the semiconductor laser element according to an aspect of the invention, the protective layer is made from metal.

In the semiconductor laser element according to an aspect of the invention, the protective layer has higher reflectivity than reflectivity of the upper electrode with respect to a wavelength of light emitted from the light-emitting layer.

A method of manufacturing a semiconductor laser element according to an aspect of the invention includes the steps of: forming a first-conductivity-type semiconductor layer on a substrate; forming a light-emitting layer on the first-conductivity-type semiconductor layer; forming a second-conductivity-type semiconductor layer on the light-emitting layer; forming a transparent conductive layer on the second-conductivity-type semiconductor layer; forming a protective layer having conductivity on the transparent conductive layer; removing part of the protective layer, part of the transparent conductive layer, and part of the second-conductivity-type semiconductor layer, and forming side surfaces of the protective layer, side surfaces of the transparent conductive layer, and a protrusion in a strip form of the second-conductivity-type semiconductor layer; covering, by a dielectric film, side surfaces of the protrusion in the strip form of the second-conductivity-type semiconductor layer, the side surfaces of the transparent conductive layer, and the side surfaces of the protective layer; and forming an upper electrode on the protective layer, in which, in the step of forming the protective layer, a whole of an upper surface of the transparent conductive layer is covered by the protective layer, and in the step of covering by the dielectric film, part of an upper surface of the protective layer is covered by the dielectric film.

In the method of manufacturing a semiconductor laser element according to an aspect of the invention, the dielectric film is formed on the side surfaces of the second-conductivity-type semiconductor layer, the side surfaces of the transparent conductive layer, the side surfaces of the protective layer, and the upper surface of the protective layer, and part of the dielectric film formed on the upper surface of the protective layer is removed by etching, in the step of covering by the dielectric film.

In the method of manufacturing a semiconductor laser element according to an aspect of the invention, the step of forming the transparent conductive layer further includes the steps of: forming a first transparent conductive layer made from ITO; performing heat treatment on the first transparent conductive layer; forming a second transparent conductive layer made from ZnO; and performing heat treatment on the second transparent conductive layer.

In the method of manufacturing a semiconductor laser element according to an aspect of the invention, the step of forming the transparent conductive layer further includes the steps of: forming a first transparent conductive layer made from ITO; performing heat treatment on the first transparent conductive layer in an atmosphere containing oxygen; forming a second transparent conductive layer made from ITO; and performing heat treatment on the second transparent conductive layer in an atmosphere containing less oxygen than in the step of performing heat treatment on the first transparent conductive layer.

### BRIEF DESCRIPTION OF DRAWINGS

FIG. 1A is a perspective view schematically illustrating a configuration of a semiconductor laser element according to an embodiment of the invention.

FIG. 1B is a sectional view schematically illustrating the configuration of the semiconductor laser element according to the embodiment of the invention.

FIG. 2 is a sectional view schematically illustrating a manufacturing step (1) of the semiconductor laser element according to the embodiment of the invention.

FIG. 3 is a sectional view schematically illustrating a manufacturing step (2) of the semiconductor laser element according to the embodiment of the invention.

FIG. 4 is a sectional view schematically illustrating a manufacturing step (3) of the semiconductor laser element according to the embodiment of the invention.

FIG. 5 is a sectional view schematically illustrating a manufacturing step (4) of the semiconductor laser element according to the embodiment of the invention.

FIG. 6 is a sectional view schematically illustrating a manufacturing step (5) of the semiconductor laser element according to the embodiment of the invention.

FIG. 7 is a sectional view schematically illustrating a manufacturing step (6) of the semiconductor laser element according to the embodiment of the invention.

FIG. 8 is a perspective view schematically illustrating the manufacturing step (6) of the semiconductor laser element according to the embodiment of the invention.

FIG. 9 is a perspective view schematically illustrating another state of the manufacturing step (6) of the semiconductor laser element according to the embodiment of the invention.

FIG. 10 is a sectional view schematically illustrating a manufacturing step (7) of the semiconductor laser element according to the embodiment of the invention.

### DESCRIPTION OF EMBODIMENTS

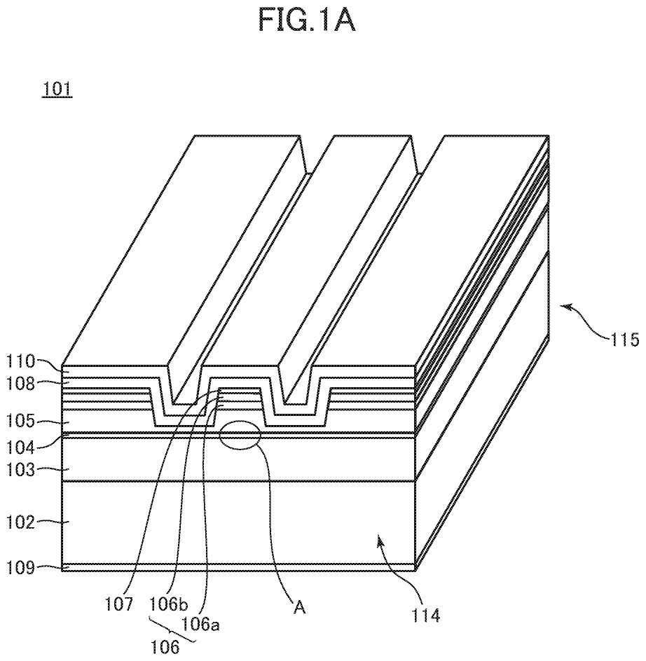

Hereinafter, an embodiment of the invention will be described in detail. FIG. 1A is a perspective view schematically illustrating a configuration of a semiconductor laser element according to the embodiment of the invention. FIG. 1B is a sectional view schematically illustrating the configuration of the semiconductor laser element according to the embodiment of the invention.

As illustrated in FIGS. 1A and 1B, a semiconductor laser element 101 is, for example, a semiconductor laser element of an end surface emission type that has a front-end surface 114 and a rear-end surface 115. In the semiconductor laser element 101, when current is applied, light is emitted from a light-emitting layer 104 described later, and the emitted light is amplified by being repeatedly reflected between the front-end surface 114 and the rear-end surface 115, and laser light is output from a light-emitting point A on the front-end surface 114.

In the semiconductor laser element 101, a first-conductivity-type semiconductor layer 103, the light-emitting layer 104, a second-conductivity-type semiconductor layer 105, a transparent conductive layer 106, and a protective layer 107 are formed in this order on a substrate 102.

By removing part of the protective layer 107, part of the transparent conductive layer 106, and part of the second-conductivity-type semiconductor layer 105, two grooves 112 and 112 are formed. A portion between the two grooves 112 and 112 is a ridge 111 and functions as a light wave guide. The ridge 111 is composed of a protrusion in a strip form of the second-conductivity-type semiconductor layer 105, the transparent conductive layer 106 formed thereon, and the protective layer 107 and has a strip shape as viewed from an upper surface of the semiconductor laser element 101.

Terraces 113 and 113 are formed outside the two grooves 112 and 112, and each of the terraces 113 is composed of a protrusion of the second-conductivity-type semiconductor layer 105, the transparent conductive layer 106 formed thereon, and the protective layer 107. An upper surface of the protective layer 107 on the ridge 111 and an upper surface of the protective layer 107 on the terraces 113 are flush with each other. Note that, the terraces 113 may be omitted, and portions corresponding to the terraces 113 may be removed when the grooves 112 are formed by removing part of the protective layer 107, part of the transparent conductive layer 106, and part of the second-conductivity-type semiconductor layer 105.

Part of the upper surface of the ridge 111, side surfaces of the ridge 111, a bottom surface of the grooves 112, and an upper surface and a side surface of the terraces 113 are covered by a dielectric film 108. The dielectric film 108 formed on the upper surface of the ridge 111 is partially removed so as to expose part of the protective layer 107.

An upper electrode 110 is formed on an upper surface of the dielectric film 108 and on the exposed upper surface of the protective layer 107, and the protective layer 107 and the upper electrode 110 are electrically connected to each other. Note that, the transparent conductive layer 106 may further include a first transparent conductive layer 106a and a second transparent conductive layer 106b. Furthermore, a lower electrode 109 may be arranged on a lower surface of the substrate 102.

Here, in the semiconductor laser element 101, the entire upper surface of the transparent conductive layer 106 on the ridge 111 is covered by the protective layer 107, and part of the upper surface of the protective layer 107 is covered by the dielectric film 108. The entire upper surface of the transparent conductive layer 106 on the ridge 111 is covered by the protective layer 107, and therefore, when the dielectric film 108 formed on the upper surface of the ridge 111 is partially removed by etching as described later, the transparent conductive layer 106 is protected from being etched. Moreover, since part of the upper surface of the protective layer 107 is covered by the dielectric film 108, the protective layer 107 and the transparent conductive layer 106 are in close contact and peeling of the protective layer 107 from the transparent conductive layer 106 is suppressed.

An end of the upper surface of the protective layer 107 may be covered by the dielectric film 108. Covering the end of the upper surface of the protective layer 107 by the dielectric film 108 prevents the transparent conductive layer 106 that is a lower layer from being etched by an etchant introduced from a boundary portion between side surfaces of the transparent conductive layer 106 and the protective layer 107, when the dielectric film 108 formed on the upper surface of the ridge 111 is partially removed by etching as described later.

The substrate 102 is formed of a material that supports the structure of the semiconductor laser element 101. For example, the substrate 102 is made from Si-doped n-type GaN. The material of the substrate 102 is not limited to the aforementioned material and may be, for example, sapphire, Si, or the like.

The first-conductivity-type semiconductor layer 103 is formed of a material by which generated light is confined to the light-emitting layer 104 described later. The first-conductivity-type semiconductor layer 103 is, for example, an n-type clad layer of Si-doped AlGaN. The material of the first-conductivity-type semiconductor layer 103 is not limited to the aforementioned material and may be, for example, n-type GaN, n-type AlInGaN, or the like.

In addition, a buffer layer may be formed between the substrate 102 and the first-conductivity-type semiconductor layer 103 by using a material that improves planarity of semiconductor crystal. The buffer layer is made from, for example, Si-doped AlGaN or the like.

The light-emitting layer 104 has a quantum well and is formed of a material that allows radiative recombination of an electron and a hole. Moreover, the light-emitting layer 104 may be a multi-quantum well layer composed of a plurality of barrier layers and a plurality of well layers. For example, each of the barrier layers is made from GaN and each of the well layers is made from InGaN. The mixed crystal ratio of the well layer is able to be adjusted appropriately in accordance with the wavelength of an oscillating laser. The material of the light-emitting layer 104 is not limited to the aforementioned material, and the barrier layer may be made from, for example, undoped AlGaN or the like, and the well layer may be made from, for example, GaN, AlGaN, or the like.

In addition, a lower guide layer made from a material by which laser oscillation light is confined to the light-emitting layer 104 may be formed between the first-conductivity-type semiconductor layer 103 and the light-emitting layer 104. The lower guide layer may be made from, for example, InGaN or the like.

The second-conductivity-type semiconductor layer 105 is formed of a material by which generated light is confined to the light-emitting layer 104. For example, the second-conductivity-type semiconductor layer 105 is a p-type clad layer of Mg-doped AlGaN. Part of the second-conductivity-type semiconductor layer 105 is removed to form a protrusion. The material of the second-conductivity-type semiconductor layer 105 is not limited to the aforementioned material and may be, for example, p-type GaN, p-type AlInGaN, or the like.

In addition, an upper guide layer made from a material by which laser oscillation light is confined to the light-emitting layer 104 may be formed between the light-emitting layer 104 and the second-conductivity-type semiconductor layer 105. The upper guide layer may be made from, for example, InGaN.

The transparent conductive layer 106 is made from a material having conductivity and high transparency with respect to the laser-emitted light, and the transparent conductive layer 106 is made from, for example, ITO (indium tin oxide). The material of the transparent conductive layer 106 is not limited to the aforementioned material and may be, for example, ZnO, AZO (Al-doped ZnO), GZO (Ga-doped ZnO), IZO (In-doped ZnO), FTO (F-doped SnO₂), ATO (Sb-doped SnO₂), or the like.

Since the transparent conductive layer 106 has an electrical resistance lower than the second-conductivity-type semiconductor layer 105, the operating voltage is reduced, for example, by reducing a thickness of the protrusion of the second-conductivity-type semiconductor layer 105 and arranging the transparent conductive layer 106 as the thickness is reduced. Further, by arranging the transparent conductive layer 106 between the second-conductivity-type semiconductor layer 105 and the upper electrode 110, the distance between the light-emitting layer 104 and the upper electrode 110 increases and loss of light due to light absorption by the upper electrode 110 is reduced.

Moreover, a refractive index of the transparent conductive layer 106 with respect to light emitted from the light-emitting layer 104 may be lower than a refractive index of the second-conductivity-type semiconductor layer 105 with respect to the light emitted from the light-emitting layer 104. When the refractive index of the transparent conductive layer 106 is lower than the refractive index of the second-conductivity-type semiconductor layer 105, the light emitted from the light-emitting layer 104 is reflected at a boundary between the transparent conductive layer 106 and the second-conductivity-type semiconductor layer 105, and light is thus confined more tightly to the vicinity of the light-emitting layer 104 and loss of light is reduced. Accordingly, the light is easily saturated in the light wave guide even when a driving current is small, thus making it possible to perform laser oscillation in a state with a small threshold.

Furthermore, the transparent conductive layer 106 may include a plurality of layers. For example, the transparent conductive layer 106 may include the first transparent conductive layer 106a and the second transparent conductive layer 106b that is formed on the first transparent conductive layer 106a, and the refractive index of the second transparent conductive layer 106b with respect to the light emitted from the light-emitting layer 104 may be lower than the refractive index of the first transparent conductive layer 106a with respect to the light emitted from the light-emitting layer 104. For example, the first transparent conductive layer 106a is made from ITO and the second transparent conductive layer 106b is made from ZnO. When the refractive index of the second transparent conductive layer 106b is lower than the refractive index of the first transparent conductive layer 106a, the light is easily reflected at a boundary between the second transparent conductive layer 106b and the first transparent conductive layer 106a, so that more light is confined to the light wave guide and loss of light is further reduced.

Furthermore, the transparent conductive layer 106 may include a plurality of layers. For example, the transparent conductive layer 106 may include the first transparent conductive layer 106a and the second transparent conductive layer 106b that is formed on the first transparent conductive layer 106a, and electrical resistance of the second transparent conductive layer 106b may be lower than that of the first transparent conductive layer 106a. Since the second transparent conductive layer 106b has lower electrical resistance than the first transparent conductive layer 106a, the operating voltage of the semiconductor laser element 101 is able to be further reduced while a certain level of transparency is ensured.

Here, the first transparent conductive layer 106a and the second transparent conductive layer 106b may be made from, for example, ITO, and the first transparent conductive layer 106a may contain more oxygen than the second transparent conductive layer 106b. The transparency of ITO increases as more oxygen is contained and electrical resistance of ITO decreases as less oxygen is contained, and the transparency and a magnitude of the electrical resistance are in a trade-off relation. Here, when the first transparent conductive layer 106a close to the light-emitting layer 104 is made from ITO that contains more oxygen than the second transparent conductive layer 106b, the transparent conductive layer 106 becomes more transparent and loss of light is thus reduced. On the other hand, when the second transparent conductive layer 106b distant from the light-emitting layer 104 is made from ITO that contains less oxygen than the first transparent conductive layer 106a, the electrical resistance is reduced and it is thus possible to further reduce the operating voltage of the semiconductor laser element 101.

The protective layer 107 is made from a conductive material that protects the transparent conductive layer 106 from an etchant in a step of removing the dielectric film 108 on the ridge 111 described later, and an example thereof includes Ag. The material of the protective layer 107 is not limited to the aforementioned material and may be, for example, Ta or Ir.

Here, the protective layer 107 may be made from metal. When the protective layer 107 is made from metal, light emitted from the light-emitting layer 104 is reflected by the protective layer 104, reducing loss of light.

Moreover, the protective layer 107 may have higher reflectivity than the upper electrode 110 with respect to the wavelength of light emitted from the light-emitting layer 104. When the reflectivity of the protective layer 107 is higher than the reflectivity of the upper electrode 110, light is reflected by the protective layer 107 without being absorbed by the upper electrode 110, reducing loss of light.

The dielectric film 108 is made from a material having an electrical insulation property, and an example thereof includes aluminum oxide. The material of the dielectric film 108 is not limited to the aforementioned material and may be, for example, silicon oxide, zirconia, silicon nitride, aluminum nitride, gallium nitride, silicon oxynitride, aluminum oxynitride, or the like.

The lower electrode 109 is formed of a metal material in electrical contact with the substrate 102 and may have a single layer or a plurality of layers. The material may be selected from, for example, Au, In, Ge, Ti, W, Ta, Nb, Ni, Pt, and the like. The lower electrode 109 does not need to cover the entire surface of the substrate 102 and does not necessarily cover, for example, the vicinity of the front-end surface 114 or the vicinity of the rear-end surface 115.

The upper electrode 110 is formed of a metal material in electrical contact with the protective layer 107 and may have a single layer or a plurality of layers. The material may be selected from, for example, Au, In, Ge, Ti, W, Ta, Nb, Ni, Pt, and the like. The upper electrode 110 may cover or does not necessarily cover entire surfaces of the ridge 111, the terraces 113, and the grooves 112. The upper electrode 110 does not necessarily cover, for example, the vicinity of the front-end surface 114 or the vicinity of the rear-end surface 115.

Moreover, a surface of the upper electrode 110 on an upper side of the ridge 111 and a surface of the upper electrode 110 on an upper side of the terraces 113 may be flush. When the surface of the upper electrode 110 on the upper side of the ridge 111 and the surface of the upper electrode 110 on the upper side of the terraces 113 are flush, stress applied to the ridge 111 is dispersed to the terraces 113 at the time of so-called junction-down bonding in which the upper electrode 110 is bonded to a sub-mount or a heat sink, and breakage of the ridge 111 is thus prevented.

Furthermore, though not illustrated, a coating film may be formed on the front-end surface 114 or on the rear-end surface 115. The coating film protects an end surface of the wave guide and controls reflectivity thereof. The coating film on the front-end surface 114 is formed to have reflectivity lower than that of the coating film on the rear-end surface 115. The coating film has a layered structure including, for example, AlN and Al₂O₃. Note that, it is possible to omit any one or both of the coating film on the front-end surface 114 side and the coating film on the rear-end surface 115 side.

[Method of Manufacturing Semiconductor Laser Element]

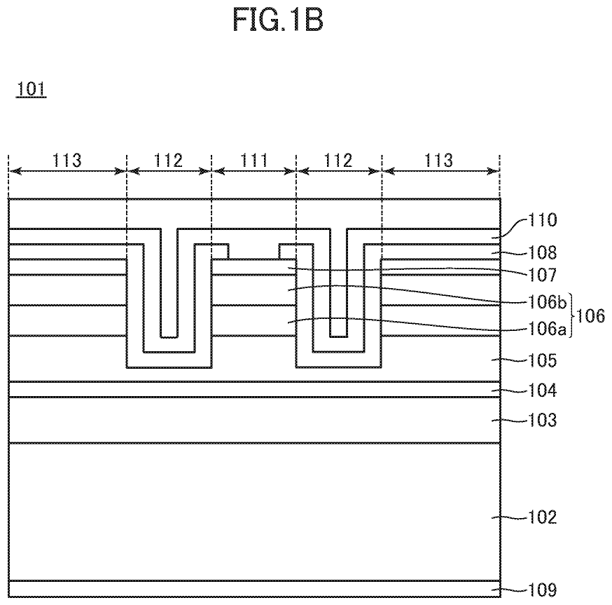

In an embodiment, the semiconductor laser element is manufactured by, for example, a MOCVD method. FIGS. 2 to 10 are sectional views and perspective views each schematically illustrating part of a manufacturing step of the semiconductor laser element according to the embodiment. Hereinafter, detailed description will be given with reference to FIGS. 2 to 10.

First, as illustrated in FIG. 2, the first-conductivity-type semiconductor layer 103 is formed on the substrate 102. Specifically, for example, the substrate 102, which has a wafer shape and is made from Si—GaN, is placed in a MOCVD apparatus and the first-conductivity-type semiconductor layer 103 made from Si—(Al_{0.1}Ga_{0.9})N is layered thereon.

Next, the light-emitting layer 104 is formed on the first-conductivity-type semiconductor layer 103. Specifically, for example, the light-emitting layer 104 is formed by consecutively layering a barrier layer made from non-doped GaN and a well layer made from non-doped InGaN twice and layering a barrier layer made from non-doped GaN again. The mixed crystal ratio and layer thickness of the well layer are appropriately adjusted so as to achieve oscillation at a laser wavelength of 520 nm, for example.

Next, the second-conductivity-type semiconductor layer 105 is formed on the light-emitting layer 104. Specifically, for example, the second-conductivity-type semiconductor layer 105 made from Mg—(Al_{0.05}Ga_{0.95}N) is layered.

Next, the substrate 102 on which the layers are layered is removed from the MOCVD apparatus, and a wafer having a multilayer film of a semiconductor is thus obtained.

Next, the transparent conductive layer 106 is formed on the second-conductivity-type semiconductor layer 105. Specifically, for example, 1 μm of ITO is layered onto an upper surface of the wafer having the multilayer film of the semiconductor by EB deposition.

Next, the wafer on which ITO is layered is placed in an annealing furnace to be subjected to annealing. The annealing is conducted for 5 minutes in an atmosphere containing 5% oxygen at 650° C. The annealing in the atmosphere containing oxygen provides transparency with respect to laser-emitted light, and a wafer having the transparent conductive layer 106 is thus obtained.

Here, the transparent conductive layer 106 may have a plurality of layers made from mutually different materials. Specifically, for example, 0.5 μm of the first transparent conductive layer 106a made from ITO is formed, and next, the first transparent conductive layer 106a is subjected to heat treatment, and after that, 0.5 μm of the second transparent conductive layer 106b made from ZnO is formed, and subsequently, the second transparent conductive layer 106b is subjected to heat treatment.

Moreover, the transparent conductive layer 106 may have a plurality of layers made from the same material. Specifically, for example, 0.5 μm of the first transparent conductive layer 106a made from ITO is formed, and next, the first transparent conductive layer 106a is subjected to heat treatment in an atmosphere containing oxygen, and after that, 0.5 μm of the second transparent conductive layer 106b made from ITO is formed, and subsequently, the second transparent conductive layer 106b is subjected to heat treatment in an atmosphere containing less oxygen than in the case where the first transparent conductive layer 106a is subjected to heat treatment.

Next, the protective layer 107 is formed on the transparent conductive layer 106. Specifically, for example, Ag is formed by EB deposition, and a wafer having the protective layer 107 as illustrated is thus obtained.

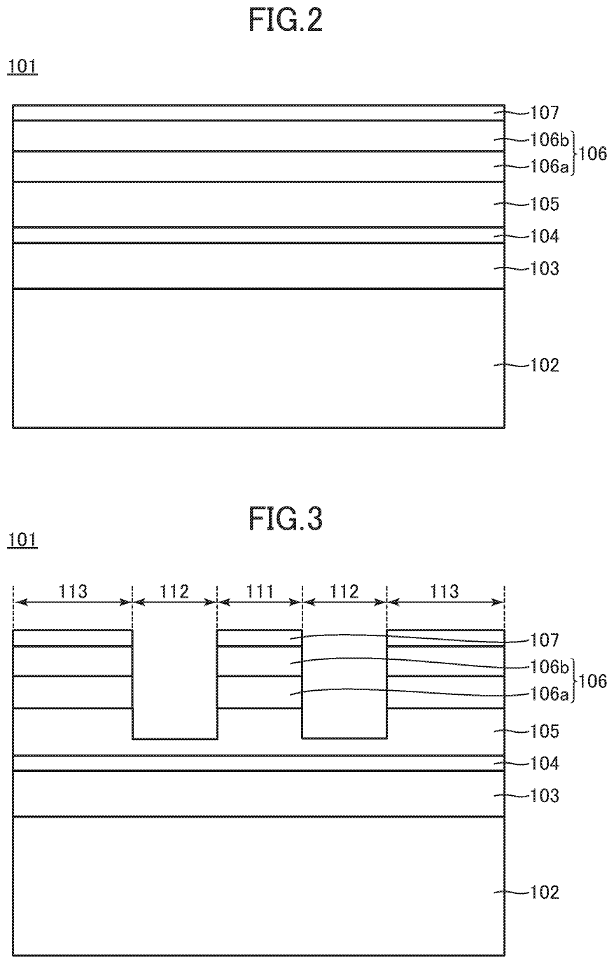

Then, as illustrated in FIG. 3, part of the protective layer 107, part of the transparent conductive layer 106, and part of the second-conductivity-type semiconductor layer 105 are removed. Specifically, for example, first, a portion of the upper surface of the protective layer 107, which corresponds to the ridge 111 and the terraces 113, is masked by photolithography. The ridge 111 is masked in a strip shape as viewed from an upper surface. Next, a portion not masked in the protective layer 107 is removed by etching. An etchant is, for example, NH₃+H₂O₂. After that, part of the transparent conductive layer 106 and part of the second-conductivity-type semiconductor layer 105 are removed by, for example, dry etching. The second-conductivity-type semiconductor layer 105 includes a protrusion in a strip form, and side surfaces of the transparent conductive layer 106 and side surfaces of the protective layer 107 are exposed. After that, the mask is removed, and a wafer on which the ridge 111 is formed is thus obtained. The grooves 112 are formed on both sides of the ridge 111 and the terraces 113 are formed outside of the grooves 112.

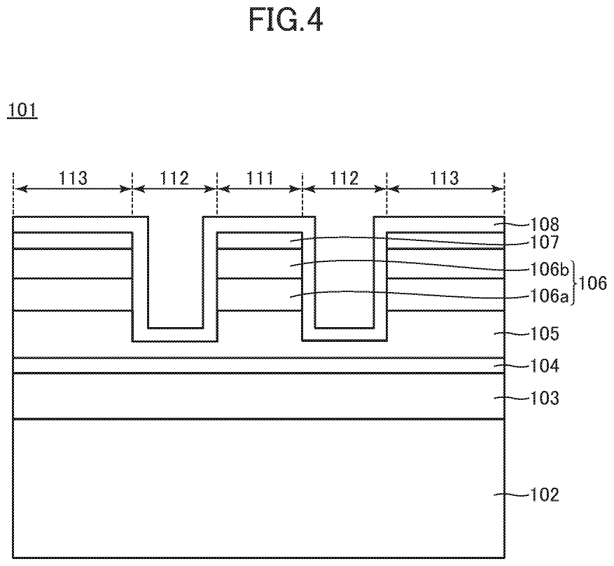

Next, as illustrated in FIG. 4, side surfaces of the protrusion in the strip form of the second-conductivity-type semiconductor layer 105, the side surfaces of the transparent conductive layer 106, and the side surfaces of the protective layer 107 are covered by the dielectric film 108. Specifically, for example, the dielectric film 108 made from SiO₂ is formed on the upper surface and side surfaces of the ridge 111, a bottom surface of the grooves 112, and an upper surface and a side surface of the terraces 113 by electron cyclotron resonance plasma chemical vapor deposition (ECR plasma CVD).

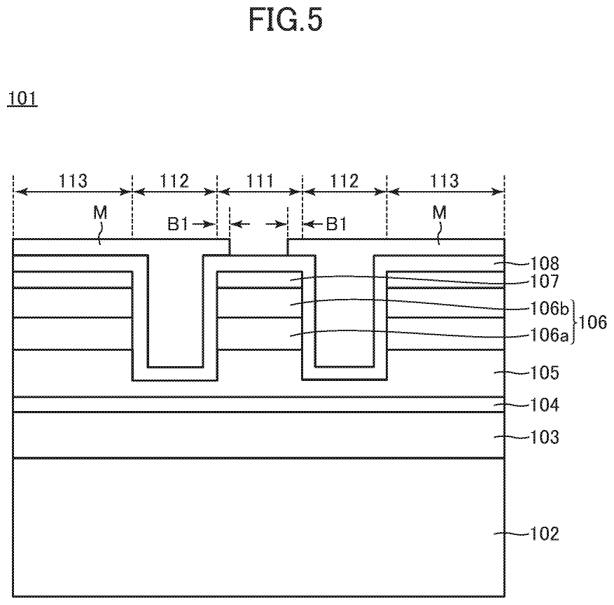

After that, as illustrated in FIG. 5, part of the dielectric film 108 is masked. Specifically, for example, first, part of the dielectric film 108 is masked with a mask M by photolithography. Next, part of the mask M, which is on an upper side of the ridge 111, is removed and part of the dielectric film 108 is exposed. Here, the mask M at an end of the protective layer 107, more specifically, of a peripheral portion B1 of the protective layer 107 in a longitudinal direction of the ridge 111 is not removed.

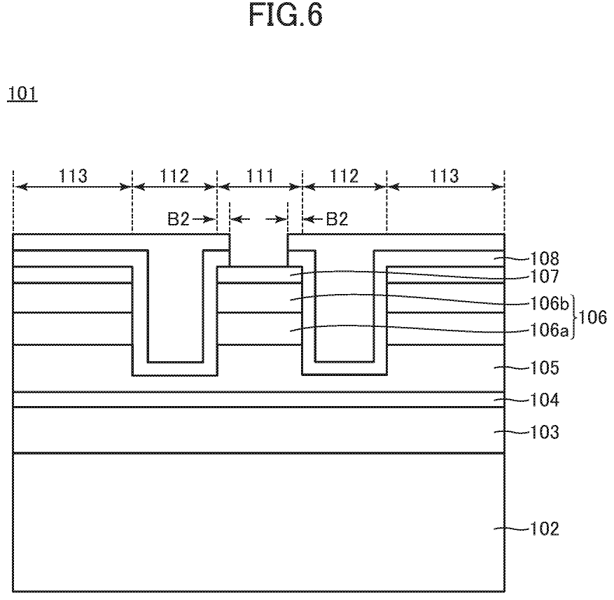

Sequentially, as illustrated in FIG. 6, part of a surface of the dielectric film 108 is removed and part of the protective layer 107 is exposed. Specifically, for example, the dielectric film 108 that is not masked is removed by etching using hydrofluoric acid. Here, a whole of an upper surface of the transparent conductive layer 106 is not etched due to the protective layer 107. Moreover, the end of the protective layer 107 is covered by a portion B2 of the dielectric film 108, and thus an etchant does not enter a boundary portion between a side surface of the protective layer 107 and the dielectric film 108. Accordingly, a side surface of the transparent conductive layer 106 is also not etched. Thus, the ridge 111 that includes the transparent conductive layer 106 is able to be easily formed without using a method, such as an etching back method, in which management of an etching rate or an etching time is complicated and which has many steps.

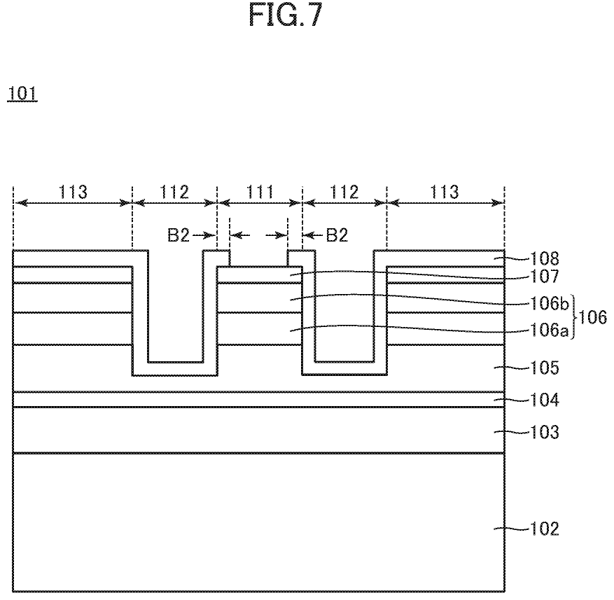

Next, by removing the mask M, as illustrated in FIG. 7, the dielectric film 108 that covers the side surfaces of the protrusion in the strip form of the second-conductivity-type semiconductor layer 105, the side surfaces of the transparent conductive layer 106, and the side surfaces of the protective layer 107 is formed.

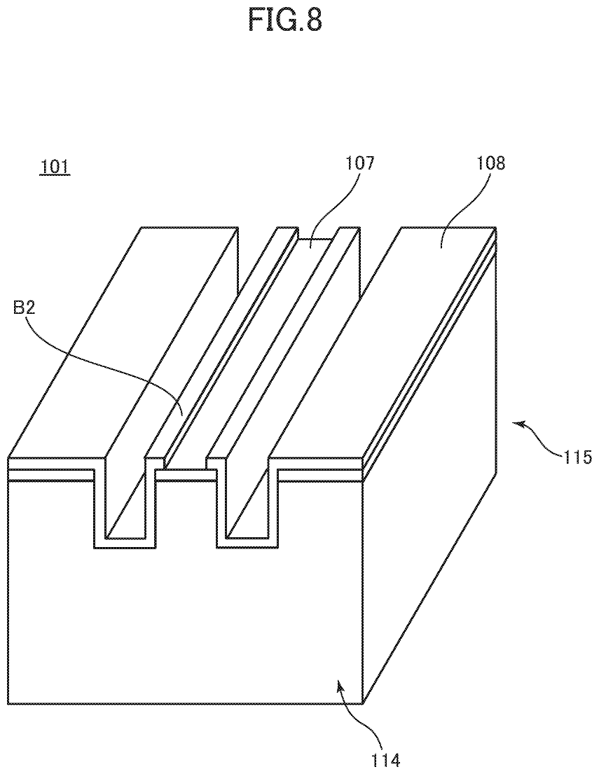

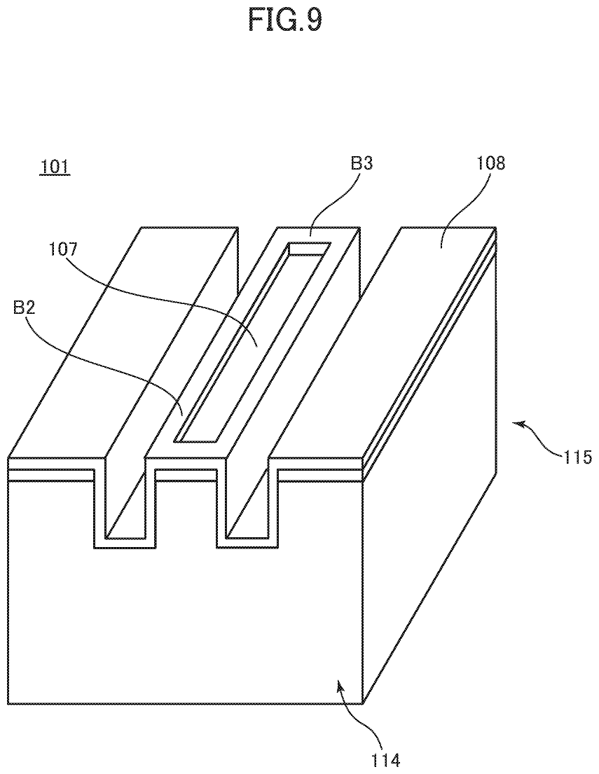

Here, with reference to FIGS. 8 and 9, a shape of the dielectric film will be described more specifically. FIG. 8 is a perspective view schematically illustrating a state in which part of the protective layer 107 is exposed and which is illustrated also in FIG. 7. The protective layer 107 has a rectangular shape having a long side parallel to the longitudinal direction of the ridge as viewed from the upper surface and a short side vertical to the longitudinal direction of the ridge. The protective layer 107 is opened into a strip shape and a periphery of the long side is covered by the portion B2 of the dielectric film 108. Here, the short side is not covered by the dielectric film 108, but in a shape of the wafer, the front-end surface 114 of the semiconductor laser element 101 is continuous with a rear-end surface 115 of a semiconductor laser element 101 that is adjacent thereto, and the transparent conductive layer 106 is thus not affected by etching.

Moreover, FIG. 9 is a perspective view schematically illustrating another state in which part of the protective layer 107 is exposed and which is illustrated also in FIG. 7. The protective layer 107 may have the long side covered by the portion B2 of the dielectric film 108 as viewed from the upper surface and the short side covered by a portion B3 of the dielectric film 108. Since the short side of the protective layer 107 is covered by the portion B3 of the dielectric film 108, current is hardly supplied to the vicinity of the front-end surface 114 and to the vicinity of the rear-end surface 115 of the semiconductor laser element 101, and damage to an end surface caused by supplying excessive current, which is called COD (catastrophic optical damage) is thus able to be suppressed.

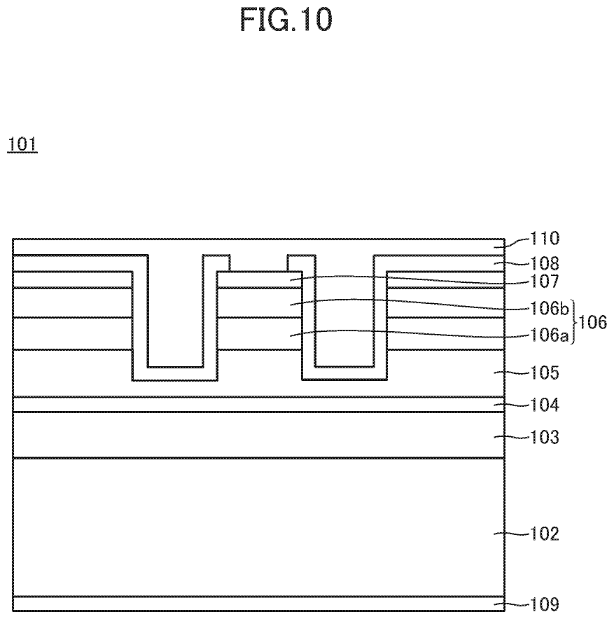

Then, as illustrated in FIG. 10, the upper electrode 110 is formed on the protective layer 107 that is exposed. Specifically, for example, Ti and Au are layered on the partially exposed upper surface of the protective layer 107 and the upper surface of the dielectric film 108 by vacuum deposition. After that, the layered Ti and Au are subjected to patterning obtained by photolithography and etching and a wafer having the upper electrode 110 is obtained.

Sequentially, the lower electrode 109 is formed. Specifically, for example, Ti and Au are layered on a lower surface of the substrate 102 by vacuum deposition. Next, the layered Ti and Au are subjected to patterning obtained by photolithography and etching and a wafer having the lower electrode 109 is obtained.

Note that, the lower electrode 109 and the upper electrode 110 are not necessarily arranged at positions which face the light-emitting layer in a vertical direction. For example, in a case where a material of the substrate 102 is nonconductive sapphire, by exposing part of a lower clad layer by etching or the like, the lower electrode 109 may be formed on the exposed part and arranged on the same side as the upper electrode 110 and the light-emitting layer.

Next, the wafer is divided into bars. Specifically, for example, by cleaving the wafer at an interval of a length of a resonator of the semiconductor laser element from a direction vertical to the ridge, laser portions divided into bars are obtained. One cleavage surface of a laser portion in a bar results in a front-end surface and the other cleavage surface thereof results in a rear-end surface.

Then, a coating film is formed on the front-end surface and the rear-end surface of the laser portions divided into bars. Specifically, for example, AlN and Al₂O₃ are layered on the front-end surface of the laser portion in the bar shape by sputtering to form a laser emitting surface. Moreover, AlN and Al₂O₃ are repeatedly layered on the rear-end surface to form a laser reflecting surface.

Lastly, the laser portion in the bar shape, on which the coating film is formed, is divided into individual chips to form semiconductor laser elements.

Note that, a material of a nitride-based semiconductor is mainly used for the semiconductor laser element disclosed in each of the embodiments of the invention, but there is no limitation thereto and, for example, a material of an AlGaInAsP-based semiconductor or ZnSe-based semiconductor is also applicable thereto. Moreover, a laser oscillation wavelength of the invention is not limited to the wavelength in each of the embodiments, and the invention is able to be applied to an oscillation wavelength of ultraviolet light, visible light, infrared light, or the like.

The invention is not limited to each of the embodiments described above, and may be modified in various manners within the scope indicated in the claims and an embodiment achieved by appropriately combining technical means disclosed in different embodiments is also encompassed in the technical scope of the invention. Further, by combining the technical means disclosed in each of different embodiments, a new technical feature may be formed.

### REFERENCE SIGNS LIST

101 semiconductor laser element
102 substrate
103 first-conductivity-type semiconductor layer
104 light-emitting layer
105 second-conductivity-type semiconductor layer
106 transparent conductive layer
106a first transparent conductive layer
106b second transparent conductive layer
107 protective layer
108 dielectric film
109 lower electrode
110 upper electrode
111 ridge
112 groove
113 terrace
114 front-end surface
115 rear-end surface
A light-emitting point
M mask

1. A semiconductor laser element comprising:
a substrate;
a first-conductivity-type semiconductor layer that is formed on the substrate;
a light-emitting layer that is formed on the first-conductivity-type semiconductor layer;
a second-conductivity-type semiconductor layer that is formed on the light-emitting layer and includes a protrusion in a strip form;
a transparent conductive layer that is formed on the protrusion of the second-conductivity-type semiconductor layer;
a protective layer that is formed on the transparent conductive layer and has conductivity;
a dielectric film that covers side surfaces of the protrusion of the second-conductivity-type semiconductor layer, side surfaces of the transparent conductive layer, and side surfaces of the protective layer; and
an upper electrode that is formed on the protective layer, wherein
a whole of an upper surface of the transparent conductive layer is covered by the protective layer, and
part of an upper surface of the protective layer is covered by the dielectric film.

2. The semiconductor laser element according to claim 1, wherein an end of the upper surface of the protective layer is covered by the dielectric film.

3. The semiconductor laser element according to claim 1, wherein a refractive index of the transparent conductive layer with respect to light emitted from the light-emitting layer is lower than a refractive index of the second-conductivity-type semiconductor layer with respect to the light emitted from the light-emitting layer.

4. The semiconductor laser element according to claim 1, wherein
the transparent conductive layer includes a first transparent conductive layer and a second transparent conductive layer that is formed on the first transparent conductive layer, and
a refractive index of the second transparent conductive layer with respect to light emitted from the light-emitting layer is lower than a refractive index of the first transparent conductive layer with respect to the light emitted from the light-emitting layer.

5. The semiconductor laser element according to claim 1, wherein
the transparent conductive layer includes a first transparent conductive layer and a second transparent conductive layer that is formed on the first transparent conductive layer, and
the second transparent conductive layer has an electrical resistance lower than an electrical resistance of the first transparent conductive layer.

6. The semiconductor laser element according to claim 5, wherein
the first transparent conductive layer and the second transparent conductive layer are made from ITO, and the first transparent conductive layer contains more oxygen than the second transparent conductive layer.

7. The semiconductor laser element according to claim 1, wherein the protective layer is made from metal.

8. The semiconductor laser element according to claim 1, wherein the protective layer has higher reflectivity than reflectivity of the upper electrode with respect to a wavelength of light emitted from the light-emitting layer.

9. A method of manufacturing a semiconductor laser element, the method comprising the steps of:
forming a first-conductivity-type semiconductor layer on a substrate;
forming a light-emitting layer on the first-conductivity-type semiconductor layer;
forming a second-conductivity-type semiconductor layer on the light-emitting layer;
forming a transparent conductive layer on the second-conductivity-type semiconductor layer;
forming a protective layer having conductivity on the transparent conductive layer;
removing part of the protective layer, part of the transparent conductive layer, and part of the second-conductivity-type semiconductor layer, and forming side surfaces of the protective layer, side surfaces of the transparent conductive layer, and a protrusion in a strip form of the second-conductivity-type semiconductor layer;
covering, by a dielectric film, side surfaces of the protrusion in the strip form of the second-conductivity-type semiconductor layer, the side surfaces of the transparent conductive layer, and the side surfaces of the protective layer; and
forming an upper electrode on the protective layer, wherein
in the step of forming the protective layer, a whole of an upper surface of the transparent conductive layer is covered by the protective layer, and
in the step of covering by the dielectric film, part of an upper surface of the protective layer is covered by the dielectric film.

10. The method of manufacturing a semiconductor laser element according to claim 9, wherein the dielectric film is formed on the side surfaces of the second-conductivity-type semiconductor layer, the side surfaces of the transparent conductive layer, the side surfaces of the protective layer, and the upper surface of the protective layer, and part of the dielectric film formed on the upper surface of the protective layer is removed by etching, in the step of covering by the dielectric film.

11. The method of manufacturing a semiconductor laser element according to claim 9, wherein
the step of forming the transparent conductive layer further includes the steps of:
forming a first transparent conductive layer made from ITO;
performing heat treatment on the first transparent conductive layer;
forming a second transparent conductive layer made from ZnO; and
performing heat treatment on the second transparent conductive layer.

12. The method of manufacturing a semiconductor laser element according to claim 9, wherein
the step of forming the transparent conductive layer further includes the steps of:
forming a first transparent conductive layer made from ITO;
performing heat treatment on the first transparent conductive layer in an atmosphere containing oxygen;
forming a second transparent conductive layer made from ITO; and
performing heat treatment on the second transparent conductive layer in an atmosphere containing less oxygen than in the step of performing heat treatment on the first transparent conductive layer.
